(19) United States
(12) Patent Application Publication
(10) Pub. No.: US 2025/0383482 A1
(43) Pub. Date: Dec. 18, 2025

(54) DISPLAY DEVICE AND ELECTRONIC APPARATUS

(71) Applicant: SONY SEMICONDUCTOR SOLUTIONS CORPORATION, KANAGAWA (JP)

(72) Inventors: KIYOSHI KANEUCHI, KUMAMOTO (JP); MICHIHIRO KANNO, KUMAMOTO (JP)

(21) Appl. No.: 18/878,884

(22) PCT Filed: Jun. 19, 2023
(86) PCT No.: PCT/JP2023/022553

§ 371 Date: Dec. 25, 2024

(30) Foreign Application Priority Data
Jul. 12, 2022 (JP) 2022-111759

(51) Int. Cl. G02B 5/00; H10H 29/853; H10H 29/855

(52) U.S. Cl. CPC G02B 5/003; H10H 29/853; H10H 29/8552

(57) ABSTRACT

There is provided a display device including a stacked structure in which a first substrate having a display unit including a plurality of light emitting elements and a drive circuit unit provided around the display unit, and a second substrate that transmits light from the plurality of light emitting elements are stacked on each other, and a light shielding structure including a first light shielding film that covers at least a part of the drive circuit unit and a second light shielding film that covers at least a part of a region facing the drive circuit unit on a surface of the second substrate facing the first substrate.

### FIELD

The present disclosure relates to a display device and an electronic apparatus.

### BACKGROUND

In recent years, electronic apparatuses equipped with display devices such as a viewfinder and a head mounted display (HMD) that provide augmented reality (AR) and virtual reality (VR) have been actively developed in addition to television apparatuses, monitors, and the like. In these electronic apparatuses, it is required to further widen an image display surface of a display device on which an image is displayed while downsizing an outer shape.

The display device is provided with, for example, a display unit including a plurality of light emitting elements at the center and is provided with a circuit unit including a drive circuit of the display unit around the display unit, that is, at an outer peripheral portion of the display device. Then, although the drive circuit is provided with wires and electrodes including a metal film, external light or the like incident from the outside of the display device may be reflected by such wires and the like. Such reflected light causes a white blur on an outer periphery of the image displayed on the image display surface and thus deteriorates an image quality. Therefore, the display device disclosed in the Patent Literature 1 and the like is provided with an outer frame that surrounds the outer periphery of the display device and does not transmit light.

### CITATION LIST

### Patent Literature

Patent Literature 1: JP 2012-242805 A

### SUMMARY

### Technical Problem

However, since providing the outer frame as described above leads to an increase in the number of components and the number of processes, it is difficult to suppress an increase in manufacturing cost of the display device.

Therefore, the present disclosure proposes a display device and an electronic apparatus capable of suppressing an increase in manufacturing cost while suppressing reflection of light on a drive circuit unit.

### Solution to Problem

According to the present disclosure, there is provided a display device including: a stacked structure in which a first substrate having a display unit including a plurality of light emitting elements and a drive circuit unit provided around the display unit, and a second substrate that transmits light from the plurality of light emitting elements are stacked on each other; and a light shielding structure including a first light shielding film that covers at least a part of the drive circuit unit and a second light shielding film that covers at least a part of a region facing the drive circuit unit on a surface of the second substrate facing the first substrate.

Furthermore, according to the present disclosure, there is provided an electronic device equipped with a display device. The display device includes: a stacked structure in which a first substrate having a display unit including a plurality of light emitting elements and a drive circuit unit provided around the display unit, and a second substrate that transmits light from the plurality of light emitting elements are stacked on each other, and a light shielding structure including a first light shielding film that covers at least a part of the drive circuit unit and a second light shielding film that covers at least a part of a region facing the drive circuit unit on a surface of the second substrate facing the first substrate.

### BRIEF DESCRIPTION OF DRAWINGS

FIG. 1 is a schematic plan view of a display device according to an embodiment of the present disclosure and a display device of a comparative example.

FIG. 2 is a sectional view (part 1) of a display device according to a comparative example.

FIG. 3 is a sectional view (part 2) of a display device according to a comparative example.

FIG. 4 is a sectional view of a display device according to a first embodiment of the present disclosure.

FIG. 5 is a sectional view (part 3) of a display device according to a comparative example.

FIG. 6 is a sectional view (part 4) of a display device according to a comparative example.

FIG. 7 is a sectional view of a display device according to a second embodiment of the present disclosure.

FIG. 8 is a sectional view (part 1) of a display device according to a third embodiment of the present disclosure.

FIG. 9 is a sectional view (part 2) of the display device according to the third embodiment of the present disclosure.

FIG. 10 is a plan view (part 1) of a light shielding film according to the third embodiment of the present disclosure.

FIG. 11 is a plan view (part 2) of a light shielding film according to the third embodiment of the present disclosure.

FIG. 12 is a sectional view (part 1) of a light shielding film according to a fourth embodiment of the present disclosure.

FIG. 13 is a sectional view (part 2) of the light shielding film according to the fourth embodiment of the present disclosure.

FIG. 14 is a sectional view (part 3) of the light shielding film according to the fourth embodiment of the present disclosure.

FIG. 15 is a sectional view (part 4) of the light shielding film according to the fourth embodiment of the present disclosure.

FIG. 16 is a sectional view (part 5) of the light shielding film according to the fourth embodiment of the present disclosure.

FIG. 17A is an explanatory diagram (part 1) for describing a method of manufacturing a display device according to a fifth embodiment of the present disclosure.

FIG. 17B is an explanatory diagram (part 2) for describing the method of manufacturing the display device according to the fifth embodiment of the present disclosure.

FIG. 17C is an explanatory diagram (part 3) for describing the method of manufacturing the display device according to the fifth embodiment of the present disclosure.

FIG. 18A is a front view illustrating an example of an external appearance of a digital still camera.

FIG. 18B is a rear view illustrating an example of the external appearance of the digital still camera.

FIG. 19 is an external view of a head mounted display.

FIG. 20 is an external view of a see-through head mounted display.

FIG. 21 is an external view of a television apparatus.

FIG. 22 is an external view of a smartphone.

FIG. 23A is a diagram (part 1) illustrating an internal configuration of an automobile.

FIG. 23B is a diagram (part 2) illustrating an internal configuration of an automobile.

### DESCRIPTION OF EMBODIMENTS

Hereinafter, preferred embodiments of the present disclosure will be described in detail with reference to the accompanying drawings. Note that, in the present specification and the drawings, constituent elements having substantially the same functional configuration are denoted by the same reference signs to omit redundant description. In the present specification and the drawings, some of a plurality of constituent elements having substantially the same or similar functional configuration are distinguished by attaching different alphabets after the same reference signs. However, in a case where it is not particularly necessary to distinguish each of the plurality of constituent elements having substantially the same or similar functional configuration, only the same reference sign is attached.

The drawings referred to in the following description are drawings for promoting the description of the embodiments of the present disclosure and the understanding of the description, and shapes, dimensions, ratios, and the like illustrated in the drawings may be different from actual ones for the sake of clarity. Furthermore, the display device illustrated in the drawings, the constituent elements included in the display device, and the like can be appropriately modified in design in consideration of the following description and known techniques.

The description of the specific shape in the following description does not indicate only a geometrically defined shape, but also includes a case where there is an industrially acceptable difference in a manufacturing process of the display device or a shape similar to the shape.

Furthermore, in the following description, a case where the embodiments of the present disclosure are applied to a display device that displays an image will be described as an example, but the embodiments of the present disclosure are not required to be applied to such a display device, and may be applied to a lighting device that emits light and the like.

Note that the description will be given in the following order.
1. Background of embodiment of the present disclosure created by the present inventors
2. First embodiment
3. Second embodiment
4. Third embodiment
5. Fourth embodiment
6. Fifth embodiment
7. Summary
8. Application examples
9. Supplement

### 1. Background of Embodiment of the Present Disclosure Created by the Present Inventors

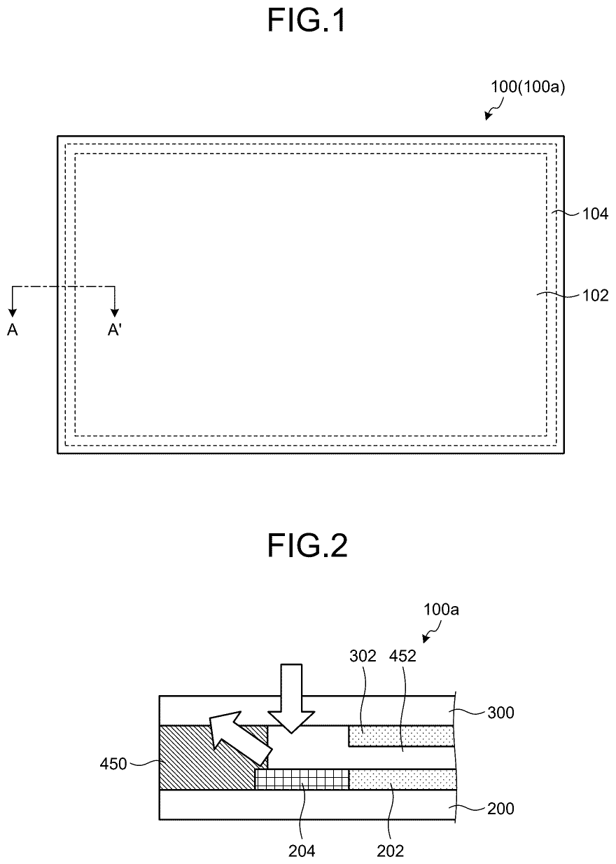

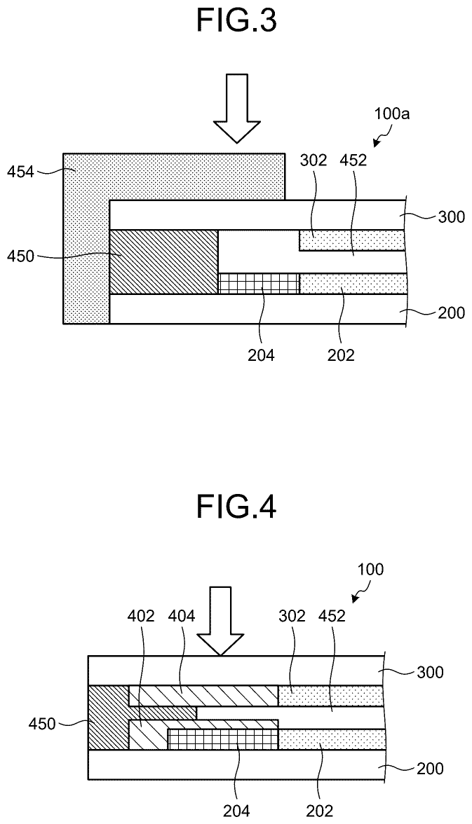

First, before describing the details of the embodiment of the present disclosure, a background in which the present inventors have created the embodiment of the present disclosure will be described with reference to FIGS. 1 to 3. FIG. 1 is a schematic plan view of a display device 100 according to the embodiment of the present disclosure and a display device 100a of a comparative example. FIGS. 2 and 3 are sectional views of the display device 100a according to a comparative example, and specifically correspond to a cross section of the display device 100a taken along line A-A′ illustrated in FIG. 1. In FIGS. 2 and 3, a vertical direction of a stacked structure of the display device 100a corresponds to a relative direction in a case where the display device 100a is disposed such that light emitted by the display device 100a is directed from below upward. Here, the comparative example means the display device 100a that the present inventors have studied before creating the embodiment of the present disclosure.

As described above, in recent years, electronic apparatuses equipped with display devices such as a viewfinder and an HMD that provide AR and VR have been actively developed in addition to television apparatuses, monitors, and the like. In these electronic apparatuses, it is required to further widen an image display surface of a display device on which an image is displayed while downsizing an outer shape. Hereinafter, an outline of such a display device 100a will be described.

Specifically, the display device 100a of the comparative example has a stacked structure (see FIG. 2) in which a back plane (BP) substrate 200 and a counter substrate 300 are stacked on each other. As illustrated in FIG. 1, a display unit 102 including a plurality of light emitting elements (for example, a light-emitting diode (LED) element) (not illustrated) is provided at a central position in plan view of the display device 100, and each of the light emitting elements radiates light to form an image. Furthermore, a circuit unit 104 including a drive circuit for driving the light emitting elements is provided around the display unit 102.

Specifically, as illustrated in FIG. 2, a light emitting unit 202 including a plurality of light emitting elements (not illustrated) and a drive circuit unit 204 provided around the light emitting unit 202 and including a drive circuit that drives the light emitting elements are provided on the BP substrate 200 side. On the other hand, a color filter (CF) unit 302 including a material such as glass that transmits light and including a plurality of color filters (not illustrated) that transmits light from the light emitting elements is provided on the counter substrate 300 side. Furthermore, the CF unit 302 is provided so as to face the light emitting unit 202.

As illustrated in FIG. 2, the BP substrate 200 and the counter substrate 300 stacked on each other are sealed by a resin 452 located between the BP substrate 200 and the counter substrate 300. Furthermore, an outer peripheral portion of the display device 100a is sealed by a sealing member 450 including resin.

By the way, as illustrated in FIG. 2, since the drive circuit unit 204 is provided with wires and electrodes including a metal film, light from the light emitting elements of the display device 100a and external light incident from outside of the display device 100a are reflected by the metal film. Then, such reflected light causes a white blur in an outer periphery of an image displayed on the display device 100a, and thus deteriorates an image quality and eventually reduces an effect of a sense of immersion by the image.

Therefore, as illustrated in FIG. 3, the display device 100a according to the comparative example is provided with an outer frame 454 that surrounds the outer periphery of the display device 100a and does not transmit light. In the comparative example, by providing such an outer frame 454, reflection of light on the metal film of the drive circuit unit 204 can be suppressed, and deterioration of the image quality can be avoided.

However, since providing the outer frame 454 leads to an increase in the number of components and the number of processes, it is difficult to suppress an increase in manufacturing cost of the display device 100a.

Therefore, the present inventors have conducted intensive studies in order to suppress an increase in manufacturing cost while suppressing reflection of light on the metal film of the drive circuit unit 204. Then, the present inventors have created an embodiment of the present disclosure described below having a configuration of the display device 100 that does not intentionally include the outer frame 454 as described above. Hereinafter, details of such embodiments of the present disclosure will be sequentially described.

### 2. First Embodiment

First, a display device 100 according to a first embodiment of the present disclosure will be described with reference to FIG. 4. FIG. 4 is a sectional view of the display device 100 according to the preset embodiment, and specifically corresponds to a cross section of the display device 100 taken along line A-A′ illustrated in FIG. 1. In FIG. 4, a vertical direction of a stacked structure of the display device 100 corresponds to a relative direction in a case where the display device 100 is disposed such that light emitted by the display device 100 is directed from below upward.

Specifically, in the present embodiment, as illustrated in FIG. 4, the display device 100 has a stacked structure in which the BP substrate (first substrate) 200 and the counter substrate (second substrate) 300 are stacked on each other. In the present embodiment, as in the comparative example, the light emitting unit (display unit) 202 including the plurality of light emitting elements (not illustrated) and the drive circuit unit 204 provided around the light emitting unit 202 and including the drive circuit for driving the light emitting elements are provided on the BP substrate 200. The CF unit 302 including a material such as glass that transmits light from the light emitting elements and including a plurality of color filters (not illustrated) that transmits light from the light emitting elements, is provided on the counter substrate 300. Then, the CF unit 302 is provided so as to face the light emitting unit 202.

As illustrated in FIG. 4, the BP substrate 200 and the counter substrate 300 stacked on each other are sealed by the resin 452 located between the BP substrate 200 and the counter substrate 300 and including a photocurable resin, for example. Furthermore, an outer peripheral portion of the stacked structure of the display device 100 in plan view is sealed by the sealing member (photocurable resin) 450 including a photocurable resin, for example. In the display device 100, which has such a sealing structure, moisture is prevented from entering the inside of the display device 100, and occurrence of substrate peeling and the like is suppressed.

In addition, in the present embodiment, as illustrated in FIG. 4, a light shielding film (first light shielding film) 402 that covers at least a part of the drive circuit unit 204 of the BP substrate 200 is provided. Furthermore, in the present embodiment, a light shielding film (second light shielding film) 404 that covers at least a part of a region not facing the light emitting unit 202, in other words, at least a part of a region facing the drive circuit unit 204 is provided on a surface of the counter substrate 300 facing the BP substrate 200. In the following description, a structure in which the light shielding films 402 and 404 are provided on both the BP substrate 200 side and the counter substrate 300 side is referred to as a light shielding structure.

Specifically, in the example illustrated in FIG. 4, the light shielding film 402 on the BP substrate 200 side covers a top surface and a side surface of the drive circuit unit 204 to suppress reflection of light on the metal film of the drive circuit unit 204. Furthermore, the light shielding film 404 on the counter substrate 300 side covers the region of the counter substrate 300 facing the drive circuit unit 204, to suppress light from the outside of the display device 100 from reaching the metal film of the drive circuit unit 204 and being reflected.

In the example illustrated in FIG. 4, the light shielding films 402 and 404 are provided such that the entire light shielding film 402 and the entire light shielding film 404 face each other. In other words, the light shielding films 402 and 404 are provided such that the entire light shielding film 402 and the entire light shielding film 404 overlap each other.

That is, in the present embodiment, due to the light shielding structure in which the light shielding films 402 and 404 are provided on both the BP substrate 200 side and the counter substrate 300 side, reflection of light on the metal film of the drive circuit unit 204 can be more reliably suppressed, and deterioration of image quality can be avoided. Furthermore, the present embodiment, which is not provided with the outer frame 454 surrounding the outer periphery of the display device 100, can suppress an increase in manufacturing cost of the display device 100.

Note that, in the present embodiment, the light shielding structure illustrated in FIG. 4 may be provided along all four sides of the rectangular display device 100 illustrated in FIG. 1. However, the present embodiment is not required to have the light shielding structure illustrated in FIG. 4 along all the four sides of the display device 100. For example, in a case where the light shielding film 402 and the sealing member 450 cannot be formed of a material having high adhesion to each other, the light shielding structure may be provided on one side or a plurality of (one or more and three or less) sides of the rectangular display device 100 in order to more reliably secure sealing of the display device 100 by the sealing member 450. Furthermore, in the present embodiment, the light shielding structure may be provided on the entire sides of the rectangular display device 100, or may be provided on a part of each side.

As described above, the light shielding structure according to the present embodiment can more reliably suppress reflection of light on the metal film of the drive circuit unit 204. Furthermore, the present embodiment, which is not provided with the outer frame 454 surrounding the outer periphery of the display device 100, can suppress an increase in manufacturing cost of the display device 100. Note that a detailed configuration of the light shielding films 402 and 404 according to the present embodiment will be described later.

### 3. Second Embodiment

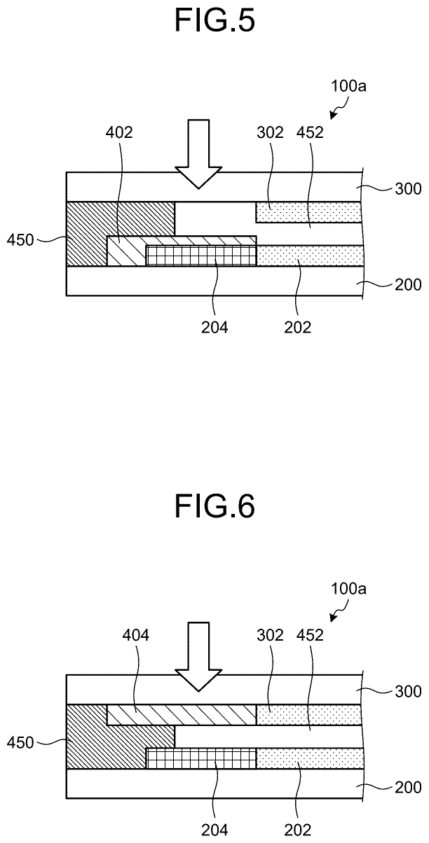

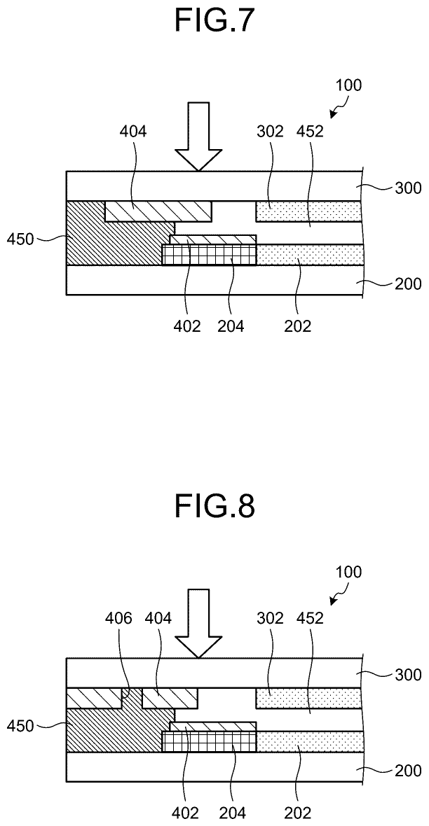

Next, a second embodiment of the present disclosure will be described with reference to FIGS. 5 to 7. FIGS. 5 and 6 are sectional views of a display device 100a according to a comparative example, and FIG. 7 is a sectional view of a display device 100 according to the present embodiment. Specifically, FIGS. 5 to 7 correspond to cross sections when display devices 100 and 100a are cut along line A-A′ illustrated in FIG. 1, and correspond to a relative direction when the display devices 100 and 100a are disposed such that light emitted by the display devices 100 and 100a is directed from below upward. Here, as described above, the comparative example means the display device 100a that the present inventors have studied before creating the embodiment of the present disclosure.

As described above, the first embodiment of the present disclosure, which is provided with the light shielding films 402 and 404 on both the BP substrate 200 side and the counter substrate 300 side, can suppress reflection of light on the metal film of the drive circuit unit 204. However, from the viewpoint of suppressing reflection of light on the drive circuit unit 204, as illustrated in FIG. 5, even the stacked structure in which the light shielding film 402 is provided on only the BP substrate 200 side can suppress reflection of light on the drive circuit unit 204 although not as reliably as the first embodiment. As illustrated in FIG. 6, even the stacked structure in which the light shielding film 404 is provided on only the counter substrate 300 side can suppress reflection of light on the drive circuit unit 204 although not as reliably as the first embodiment.

However, in the comparative example illustrated in FIG. 5, in order to more reliably suppress reflection of light at the drive circuit unit 204 by the light shielding film 402 provided only on the BP substrate 200 side, the light shielding film 402 is provided so as to cover the entire top surface and side surface of the drive circuit unit 204. In this case, although reflection of light can be suppressed, since the light shielding film 402 includes a material having lower adhesion to the sealing member 450 than the top surface (for example, silicon oxide (SiO₂) or the like) of the drive circuit unit 204, it is difficult to more reliably secure sealing by the sealing member 450 of the display device 100a. Furthermore, when sealing is insufficient, moisture may enter the inside of the display device 100a, and peeling or the like may occur.

Therefore, in order to secure the adhesion between the light shielding film 402 and the sealing member 450, it is required to set a contact area between the drive circuit unit 204 and the sealing member 450 to a predetermined size or more, and thus, it is difficult to provide the light shielding film 402 so as to cover the entire top surface and side surface of the drive circuit unit 204. In addition, in the future, since the frame will become narrower (specifically, the drive circuit unit 204 will be thinner or narrower), it is considered that it will be difficult to secure the contact area between the drive circuit unit 204 and the sealing member 450 to be greater than or equal to a predetermined size.

In the comparative example illustrated in FIG. 6, in order to more reliably suppress reflection of light on the drive circuit unit 204 by the light shielding film 404 provided only on the counter substrate 300 side, the light shielding film 404 is provided so as to cover the entire region facing the drive circuit unit 204 on the top surface of the counter substrate 300 facing the BP substrate 200. In this case, although reflection of light can be suppressed, light from the outside of the display device 100a is blocked by the light shielding film 404. Therefore, light does not reach the sealing member 450 and the resin 452 inside the display device 100a at the time of manufacturing, and there is a higher possibility that the sealing member 450 and the resin 452 are not sufficiently cured. Furthermore, when curing is insufficient, moisture may enter the inside of the display device 100a, and peeling or the like may occur.

Therefore, in the second embodiment of the present disclosure, there is proposed a light shielding structure capable of securing the contact area between the drive circuit unit 204 and the sealing member 450 of a predetermined size or more and sufficiently photocuring the sealing member 450 and the resin 452 while more reliably suppressing reflection of light on the metal film of the drive circuit unit 204.

Specifically, as illustrated in FIG. 7, in the present embodiment, the light shielding film 402 provided on the BP substrate 200 side is provided so as to cover only a part of the drive circuit unit 204, and the light shielding film 404 provided on the counter substrate 300 side is provided so as to cover only a part of the region of the counter substrate 300 facing the drive circuit unit 204. In the present embodiment, since the light shielding film 402 on the BP substrate 200 side is provided so as to expose a part of the drive circuit unit 204, the sealing member 450 and the top surface of the drive circuit unit 204 can be in direct contact with each other.

Furthermore, in the present embodiment, the light shielding films 402 and 404 are not provided so that the entire light shielding film 402 and the entire light shielding film 404 completely overlap each other. Specifically, in the example illustrated in FIG. 7, the light shielding films 402 and 404 are provided such that a part of the light shielding film 402 and a part of the light shielding film 404 face (overlap) each other, and the remaining part of the light shielding film 402 and the remaining part of the light shielding film 404 do not face (do not overlap) each other. Note that the present embodiment is not limited to the form illustrated in FIG. 7, and the light shielding films 402 and 404 may be provided so as to alternate in a stacking direction so as to suppress reflection of light on the metal film of the drive circuit unit 204. That is, in the present embodiment, the light shielding films 402 and 404 may be provided so that the entire light shielding film 402 and the entire light shielding film 404 do not completely overlap each other.

In the present embodiment, the light shielding film 404 provided on the counter substrate 300 side is provided so as to cover only a part of a region of the counter substrate 300 facing the drive circuit unit 204. Therefore, in the present embodiment, since light from the outside of the display device 100 is not completely blocked by the light shielding film 404, the light reaches the sealing member 450 and the resin 452 inside the display device 100 at the time of manufacturing. As a result, the present embodiment enables sufficient curing of the sealing member 450 and the resin 452 inside the display device 100, and thus can avoid occurrence of peeling or the like due to entry of moisture into the display device 100.

In the present embodiment, since light that cannot be blocked by the light shielding film 404 provided on the counter substrate 300 side can also be blocked by the light shielding film 402 provided on the BP substrate 200 side, reflection of light on the metal film of the drive circuit unit 204 can be suppressed.

Furthermore, in the present embodiment, since the light shielding film 402 provided on the BP substrate 200 side covers only a part of the drive circuit unit 204 and does not cover the entire drive circuit unit 204, the sealing member 450 and the top surface of the drive circuit unit 204 can be in direct contact with each other. Therefore, in the present embodiment, it is easy to set the contact area between the drive circuit unit 204 and the sealing member 450 to a predetermined size or more. In addition, in the present embodiment, it is easy to secure the contact area between the drive circuit unit 204 and the sealing member 450 to be equal to or larger than a predetermined size even in a case where the frame is narrower. That is, in the present embodiment, the contact area between the drive circuit unit 204 and the sealing member 450 can be made equal to or greater than a predetermined size, and the adhesion between the light shielding film 402 and the sealing member 450 can be secured. As a result, in the present embodiment, since sealing by the sealing member 450 of the display device 100 can be sufficiently secured, it is possible to avoid occurrence of peeling or the like due to entry of moisture into the display device 100.

### 4. Third Embodiment

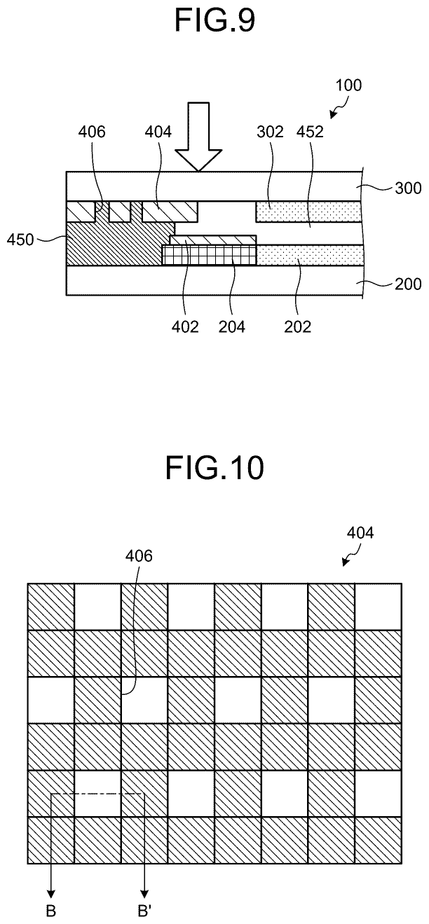

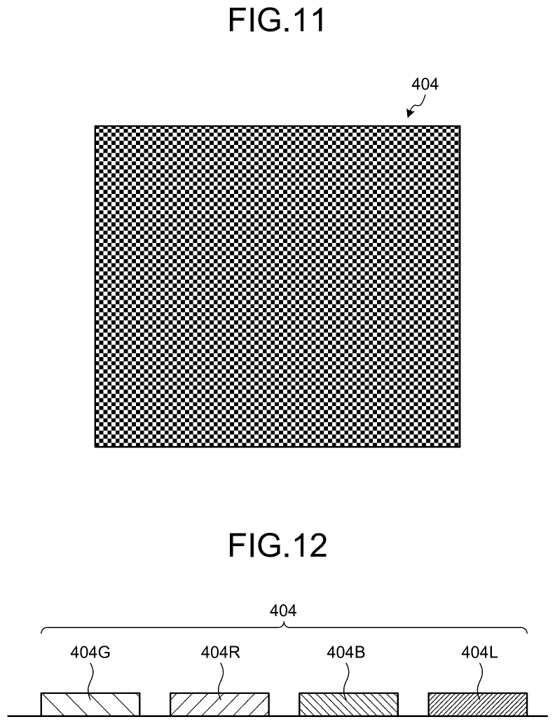

Next, a display device 100 according to a third embodiment of the present disclosure will be described with reference to FIGS. 8 to 11. FIGS. 8 and 9 are sectional views of the display device 100 according to the preset embodiment, and specifically correspond to cross sections of the display device 100 taken along line A-A′ illustrated in FIG. 1. In FIGS. 8 and 9, a vertical direction of a stacked structure of the display device 100 corresponds to a relative direction in a case where the display device 100 is disposed such that light emitted by the display device 100 is directed from below upward. Furthermore, FIGS. 10 and 11 are plan views of the light shielding film 404 according to the present embodiment.

In the second embodiment described, the light shielding film 404 provided on the counter substrate 300 side is provided so as to cover only a part of the region of the counter substrate 300 facing the drive circuit unit 204. Then, by this configuration, in the second embodiment, since light from the outside of the display device 100 is not completely blocked by the light shielding film 404, the light reaches the sealing member 450 and the resin 452 inside the display device 100 at the time of manufacturing. Therefore, in the third embodiment of the present disclosure, as in the second embodiment, an opening is provided in the light shielding film 404 in order to deliver light to the sealing member 450 and the resin 452 inside the display device 100 at the time of manufacturing.

Specifically, in the present embodiment, as illustrated in FIG. 8, the light shielding film 404 provided on the counter substrate 300 side is provided with an opening (opening) 406 for guiding light from the outside of the display device 100 to the sealing member 450 and the resin 452 inside the display device 100. Therefore, in the present embodiment, since light from the outside of the display device 100 can be efficiently guided to the sealing member 450 and the resin 452 inside the display device 100 by the opening 406, the light more reliably reaches the sealing member 450 and the resin 452 inside the display device 100 at the time of manufacturing. As a result, the present embodiment facilitates sufficient curing of the sealing member 450 and the resin 452 inside the display device 100, and thus can further avoid occurrence of peeling or the like due to entry of moisture into the display device 100.

Note that, in the present embodiment, as illustrated in FIG. 9, the number of the openings 406 provided in the light shielding film 404 is not limited to one, and may be plural.

Furthermore, in the present embodiment, since the number of the openings 406 is not limited, the light shielding film 404 may have one or a plurality of rectangular slits, or may have a lattice shape or a checkered pattern shape. In the present embodiment, the shape of the opening 406 is not limited to a rectangular shape, and may be, for example, a circular shape, an elliptical shape, a polygonal shape, or the like.

For example, in the present embodiment, the light shielding film 404 may have a lattice shape as illustrated in FIG. 10 or a checkered pattern as illustrated in FIG. 11.

However, in the present embodiment, in order to sufficiently cure the sealing member 450 and the resin 452 inside the display device 100, the area of the opening 406 of the light shielding film 404 in plan view is preferably 25% or more of the entire area of the light shielding film 404 in plan view (the area of the light shielding film 404 including the opening 406). Specifically, the present inventors prepared the light shielding film 404 in which the area of the opening 406 was variously changed, and irradiated ultra violet (UV) light from the outside of the display device 100 to confirm whether the sealing member 450 and the resin 452 inside the display device 100 were sufficiently cured. As a result, it was confirmed that the sealing member 450 and the resin 452 inside the display device 100 were sufficiently cured when the area of the opening 406 was 25% and 50%. Therefore, in the present embodiment, the area of the opening 406 of the light shielding film 404 in plan view is preferably 25% or more of the entire area of the light shielding film 404 in plan view.

In the present embodiment, as long as the light shielding films 402 and 404 are provided so as to suppress reflection of light on the metal film of the drive circuit unit 204, for example, so as to be at least staggered in the stacking direction, the light shielding film 402 on the BP substrate 200 side may also have the opening 406. Furthermore, in the present embodiment, as long as the light shielding films 402 and 404 are provided to be at least staggered in the stacking direction so as to suppress reflection of light on the metal film of the drive circuit unit 204, the light shielding film 402 may also have one or a plurality of slits, a lattice shape, or a checkered pattern shape.

As described above, in the present embodiment, since light from the outside of the display device 100 can be efficiently guided to the sealing member 450 and the resin 452 inside the display device 100 by the opening 406, the light more reliably reaches the sealing member 450 and the resin 452 inside the display device 100 at the time of manufacturing. As a result, the present embodiment facilitates sufficient curing of the sealing member 450 and the resin 452 inside the display device 100, and thus can further avoid occurrence of peeling or the like due to entry of moisture into the display device 100.

### 5. Fourth Embodiment

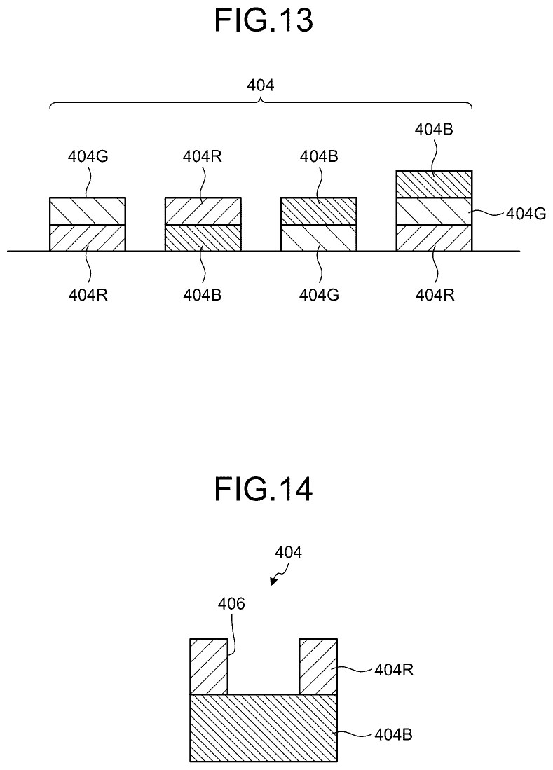

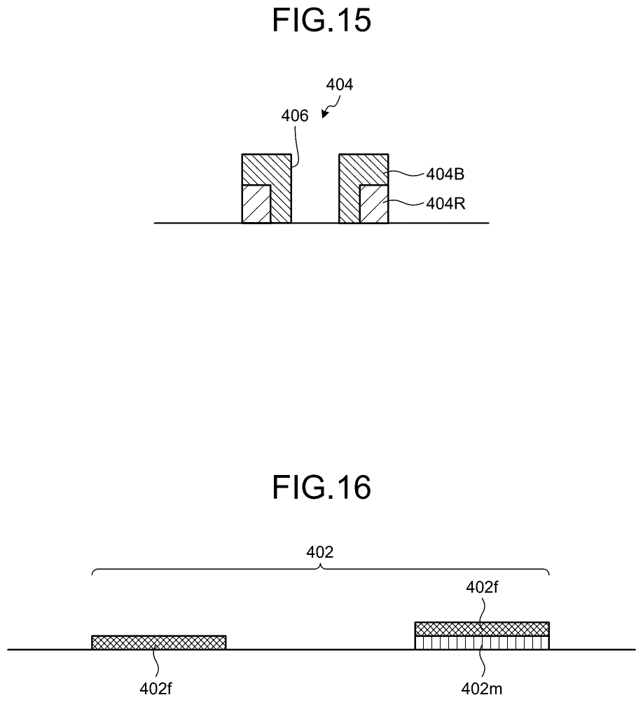

Next, light shielding films 402 and 404 according to a fourth embodiment of the present disclosure will be described with reference to FIGS. 12 to 16. FIGS. 12 and 13 are sectional views of the light shielding film 404 according to the preset embodiment, and specifically correspond to cross sections of the display device 100 taken along line A-A′ illustrated in FIG. 1. FIGS. 14 and 15 are sectional views of the light shielding film 404 according to the preset embodiment, and specifically correspond to cross sections of the light shielding film 404 taken along line B-B′ illustrated in FIG. 10. FIG. 16 is a sectional view of the light shielding film 402 according to the preset embodiment, and specifically corresponds to a cross section of the display device 100 taken along line A-A′ illustrated in FIG. 1.

In the present embodiment, the light shielding films 402 and 404 can include, for example, an organic material film or an inorganic material film as long as the material can shield light, and are not limited. Furthermore, in the present embodiment, the light shielding films 402 and 404 may be single layer films or stacked films including a plurality of layers as long as being able to shield light, and are not limited. In the present embodiment, in a case where the light shielding films 402 and 404 are stacked films, different organic material films may be stacked, different inorganic material films may be stacked, or an organic material film and an inorganic material film may be stacked, and there is no limitation.

Specifically, in the present embodiment, the light shielding film 404 provided on the counter substrate 300 side is provided on a surface side of the counter substrate 300 facing the BP substrate 200. Furthermore, in the present embodiment, as illustrated in FIG. 12, the light shielding film 404 can be formed from a color resist, and can be, for example, a green color resist (green resist) 404G, a red color resist (red resist) 404R, a blue color resist (blue resist) 404B, a black color resist (black resist) 404L, or the like. In the present embodiment, by using a color resist including the same material as the color filter provided in the CF unit 302 of the counter substrate 300 as the light shielding film 404 provided in the counter substrate 300, it is possible to effectively shield light from the outside of the display device 100 while avoiding an increase in manufacturing processes of the display device 100.

In the present embodiment, as illustrated in FIG. 13, the light shielding film 404 may be a stacked film in which different color resists are stacked. For example, the light shielding film 404 may be a stacked film in which the green color resist 404G is stacked on the red color resist 404R as illustrated on the left side in FIG. 13, or may be a stacked film in which the red color resist 404R is stacked on the blue color resist 404B as illustrated second from the left side in. FIG. 13. For example, the light shielding film 404 may be a stacked film in which the blue color resist 404B is stacked on the green color resist 404G as illustrated third from the left side in FIG. 13, or may be a stacked film in which the green color resist 404G and the blue color resist 404B are sequentially stacked on the red color resist 404R as illustrated on the right side in FIG. 13. In the present embodiment, by stacking different color resists, even in a case where light is shielded insufficiently with only one layer of color resist, the effect of light shielding of the light shielding film 404 can be enhanced by combining a plurality of different color resists. That is, in the present embodiment, the type, the combination, and the number of stacked layers of the color resists can be appropriately selected for the light shielding film 404 in accordance with the application and the like.

In the present embodiment, as in the example illustrated in FIG. 14, the light shielding film 404 may be, for example, a stacked film in which a color resist (in FIG. 14, the blue color resist 404B) having an opening 406 is stacked on a color resist (in FIG. 14, the red color resist 404R) having no opening 406.

In the present embodiment, as in the example illustrated in FIG. 15, the light shielding film 404 may have a form in which, for example, a color resist (in FIG. 15, the red color resist 404R) having a narrow opening 406 is formed so as to cover a color resist (in FIG. 15, the blue color resist 404B) having a wide opening 406.

In the present embodiment, the light shielding film 402 on the BP substrate 200 side may also include a color resist or may be a stacked film in which different color resists are stacked.

In the present embodiment, the light shielding film 402 provided on the BP substrate 200 side is provided on a surface side of the BP substrate 200 facing the counter substrate 300. In the present embodiment, as illustrated on the left side in FIG. 16, the light shielding film 402 can be formed from a low reflection metal film 402f or the like having low reflectance. Examples of the low reflection metal film 402f include titanium nitride (TiN), titanium oxynitride (TiON), chromium (Cr), chromium oxide (CrO₂), and tungsten silicide (WSi). In the present embodiment, the light shielding film 402 including such a low reflection metal film 402f can be formed subsequently after a step of forming the drive circuit unit 204 provided on the BP substrate 200. Therefore, in the present embodiment, it is possible to effectively shield light from the outside of the display device 100 while avoiding a significant increase in the manufacturing processes of the display device 100.

Furthermore, in the present embodiment, as illustrated on the right side in FIG. 16, the light shielding film 402 may be a stacked film in which the low reflection metal film 402f and a metal film 402m are stacked. Examples of the metal film 402m include titanium and aluminum (Al). In the present embodiment, by stacking the low reflection metal film 402f and the metal film 402m, the effect of light shielding of the light shielding film 402 can be enhanced by combining with the metal film 402m even when light is insufficiently shielded only with the low reflection metal film 402f. That is, in the present embodiment, the light shielding film 402 may be only the low reflection metal film 402f, or may be a stacked film in which the low reflection metal film 402f and the metal film 402m are stacked in accordance with the application or the like.

In the present embodiment, the light shielding film 404 on the counter substrate 300 side may also be the low reflection metal film 402f, or may be a stacked film in which the low reflection metal film 402f and the metal film 402m are stacked.

### 6. Fifth Embodiment

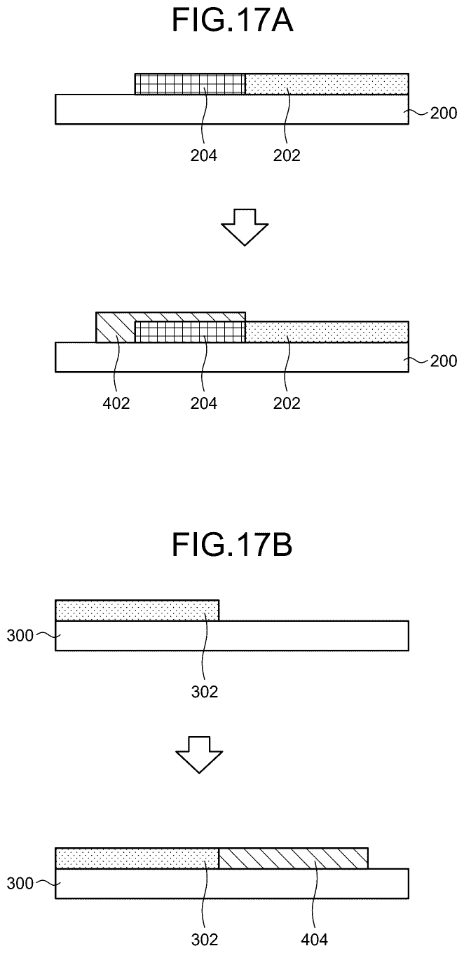

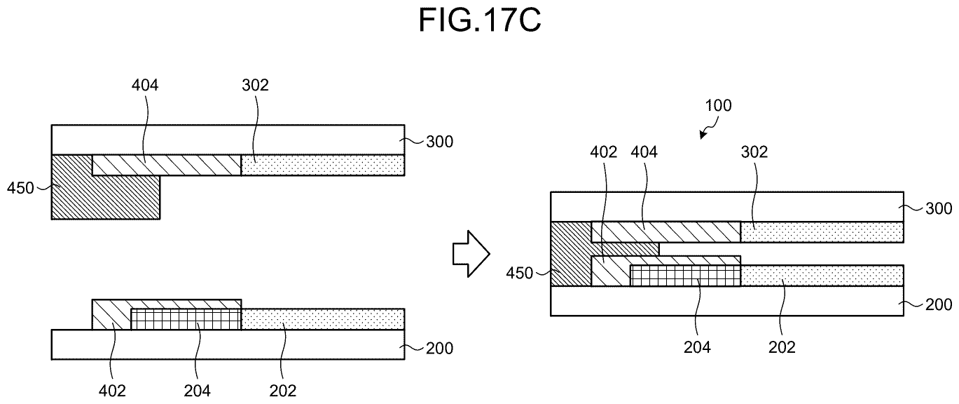

Next, some of the manufacturing processes (manufacturing method) of the display device 100 according to the present embodiment will be described with reference to FIGS. 17A to 17C. FIGS. 17A to 17C are explanatory diagrams for describing the method of manufacturing the display device 100 according to the present embodiment, and specifically correspond to the sectional view illustrated in FIG. 4.

First, the BP substrate 200 side will be described. The light emitting unit 202 including a plurality of light emitting elements (not illustrated) and the drive circuit unit 204 including a drive circuit for driving the light emitting elements around the light emitting unit 202 are formed on the BP substrate 200, and a form illustrated in the upper part of FIG. 17A can be obtained. Furthermore, the light shielding film 402 is formed so as to cover the drive circuit unit 204 of the BP substrate 200, and a form as illustrated in the lower part of FIG. 17A can be obtained.

Next, the counter substrate 300 side will be described. The CF unit 302 including a plurality of color filters (not illustrated) that transmits light from the light emitting elements is formed on the counter substrate 300, and a form as illustrated in the upper part of FIG. 17B can be obtained. Then, the light shielding film 404 is formed so as to cover a region facing the drive circuit unit 204 on the surface of the counter substrate 300 facing the BP substrate 200, and a form as illustrated in the lower part of FIG. 17B can be obtained.

Furthermore, the sealing member 450 including, for example, a photocurable resin is formed on an outer peripheral portion of the counter substrate 300 in plan view. Then, as illustrated on the left side of FIG. 17C, the BP substrate 200 and the counter substrate 300 formed in this manner are stacked so as to face each other across the resin 452 (not illustrated in FIG. 17C). Then, by irradiating UV light from the outside to cure the sealing member 450 and the resin 452, the display device 100 can be formed as illustrated on the right side in FIG. 17C.

The display device 100 according to an embodiment of the present disclosure can be manufactured by using a method, a device, and conditions used for manufacturing a general semiconductor device and electronic apparatus. Each substrate of the display device 100 according to the present embodiment can be manufactured by using, for example, an existing method of manufacturing a semiconductor device.

Examples of the above-described method include a physical vapor deposition (PVD) method, a chemical vapor deposition (CVD) method, and an atomic layer deposition (ALD) method. Examples of the PVD method include a vacuum vapor deposition method, an electron beam (EB) vapor deposition method, various sputtering methods (magnetron sputtering method, a radio frequency (RF)-direct current (DC) coupled bias sputtering method, an electron cyclotron resonance (ECR) sputtering method, a counter target sputtering method, a high frequency sputtering method, and the like), an ion plating method, a laser ablation method, a molecular beam epitaxy (MBE) method, and a laser transfer method. Examples of the CVD method include a plasma CVD method, a thermal CVD method, an organic metal (MO) CVD method, and a photo CVD method. Furthermore, other methods include an electrolytic plating method, an electroless plating method, a spin coating method, an immersion method, a cast method, a micro-contact printing method, a drop cast method, various printing methods such as a screen printing method, an inkjet printing method, an offset printing method, a gravure printing method, and a flexographic printing method, a stamping method, a spray method, and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calender coater method. Furthermore, examples of a patterning method include chemical etching such as shadow mask, laser transfer, and photolithography, and physical etching using ultraviolet rays, laser, and the like. In addition, examples of a planarization technique include a chemical mechanical polishing (CMP) method, a laser planarization method, a reflow method, and the like.

### 7. Summary

As described above, in each of the embodiments of the present disclosure, it is possible to suppress an increase in manufacturing cost of the display device 100 since the outer frame 454 is not intentionally provided while more reliably suppressing reflection of light on the metal film of the drive circuit unit 204.

Note that the technology of the present disclosure may be applied not only to the display device 100 but also to a lighting device and the like. Furthermore, the technology of the present disclosure can also be applied to an imaging device or the like including a plurality of imaging elements.

### 8. Application Examples

For example, the technology according to the present disclosure may be applied to a display unit or the like of various electronic apparatuses. Hereinafter, an example of an electronic apparatus to which the present technology can be applied will be described.

### Specific Example 1

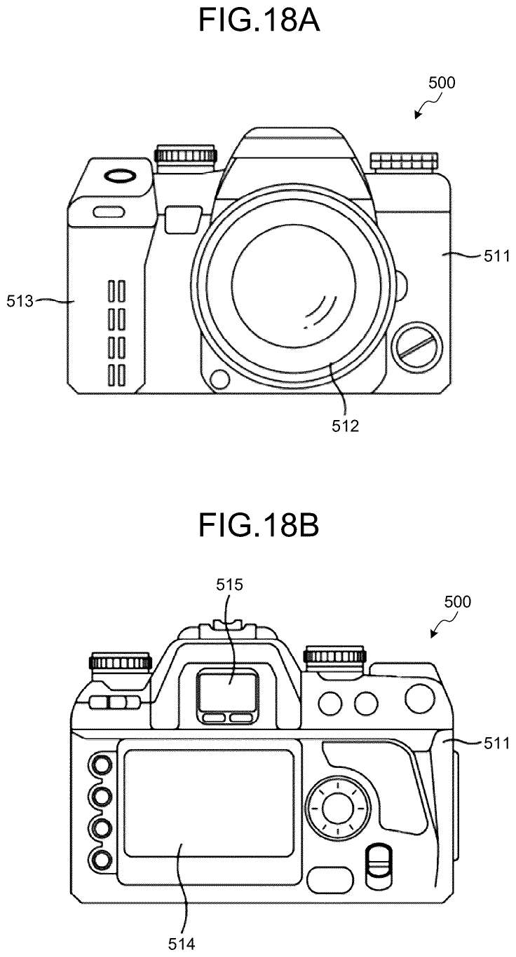

FIG. 18A is a front view illustrating an example of an external appearance of a digital still camera 500, and FIG. 18B is a rear view illustrating an example of the external appearance of the digital still camera 500. The digital still camera 500 is of a lens interchangeable single lens reflex type, and includes an interchangeable imaging lens unit (interchangeable lens) 512 substantially at a center of a front of a camera body 511, and a grip 513 to be held by a photographer on a front left side.

A monitor 514 is provided at a position shifted to the left side from a center of a back surface of the camera body 511. An electronic view finder (eyepiece window) 515 is provided above the monitor 514. By looking into the electronic view finder 515, the photographer can determine the composition by visually recognizing an optical image of a subject guided from the imaging lens unit 512. As the monitor 514 and the electronic view finder 515, the display device 100 according to the embodiment of the present disclosure can be used. Even if the digital still camera 500 is small, the image display surface can be made wider by applying the display device 100 according to the embodiment of the present disclosure.

### Specific Example 2

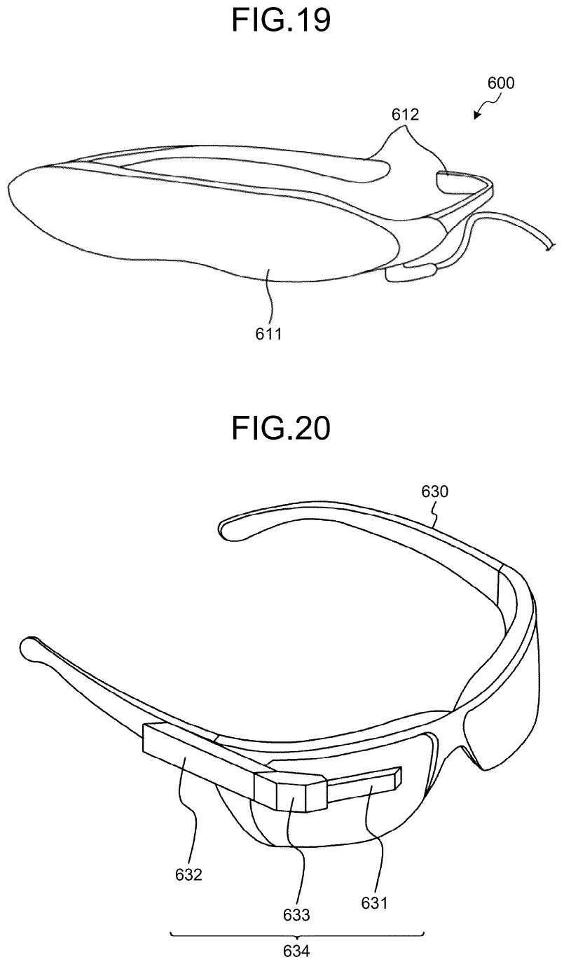

FIG. 19 is an external view of a head mounted display 600. The head mounted display 600 includes, for example, ear hooks 612 to be worn on the head of a user on both sides of an eyeglass-shaped display unit 611. In the head mounted display 600, the display device 100 according to the embodiment of the present disclosure can be used as a display unit 611. The image display surface of the head mounted display 600 can be made wider by applying the display device 100 according to the embodiment of the present disclosure.

### Specific Example 3

FIG. 20 is an external view of a see-through head mounted display 634. The see-through head mounted display 634 includes a body 632, an arm 633, and a lens barrel 631.

The body 632 is connected to an arm 643 and an eyeglass 630. Specifically, an end of the body 632 in a long side direction is coupled to the arm 633, and one side of a side surface of the body 632 is coupled to the eyeglass 630 via a connecting member. Note that the body 632 may be directly mounted on the head of a human body.

The body 632 incorporates a control board for controlling an operation of the see-through head mounted display 634 and a display unit. The arm 633 connects the body 632 and the lens barrel 631 and supports the lens barrel 631. Specifically, the arm 633 is coupled to the end of the body 632 and an end of the lens barrel 631, and fixes the lens barrel 631. Furthermore, the arm 633 incorporates a signal line for communicating data related to an image provided from the body 632 to the lens barrel 631.

The lens barrel 631 projects image light provided from the body 632 via the arm 633 toward the eyes of the user wearing the see-through head mounted display 634 through an eyepiece. In the see-through head mounted display 634, the display device 100 according to the embodiment of the present disclosure can be used for the display unit of the body 632. By applying the display device 100 according to the embodiment of the present disclosure to the see-through head mounted display 634, it is not necessary to provide the outer frame 454, and thus, the effect of a sense of immersion by an image can be further improved.

### Specific Example 4

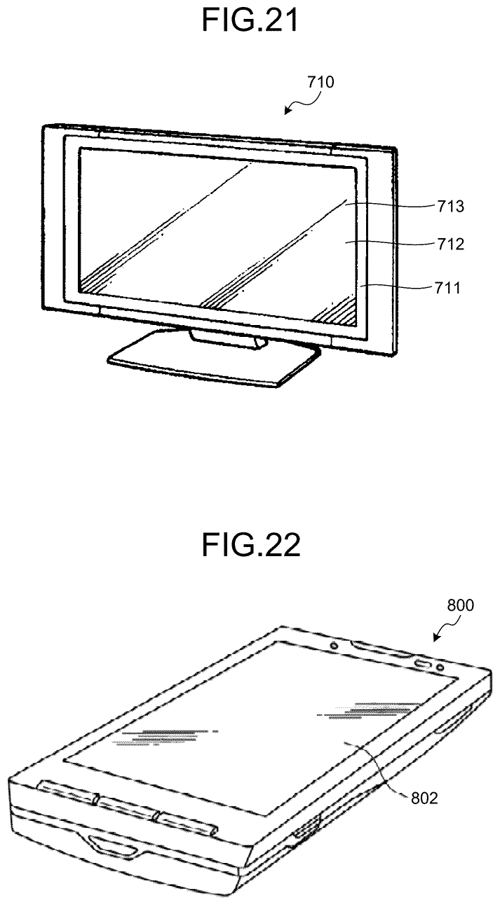

FIG. 21 illustrates an example of an external appearance of a television apparatus 710. The television apparatus 710 includes, for example, a video display screen unit 711 including a front panel 712 and a filter glass 713, and the video display screen unit 711 includes the display device 100 according to the embodiment of the present disclosure. By applying the display device 100 according to the embodiment of the present disclosure to the television apparatus 710, it is possible to further widen the image display surface while avoiding deterioration in image quality. Furthermore, by applying the display device 100 according to the embodiment of the present disclosure to the television apparatus 710, it is not necessary to provide the outer frame 454, and thus, an increase in manufacturing cost of the television apparatus 710 can be suppressed.

### Specific Example 5

FIG. 22 illustrates an example of an external appearance of a smartphone 800. The smartphone 800 includes a display unit 802 that displays various types of information, an operation unit including a button that receives an operation input by the user, and the like. The display unit 802 can be the display device 100 according to the present embodiment. The image display surface of the smartphone 800 can be made wider by applying the display device 100 according to the embodiment of the present disclosure.

### Specific Example 6

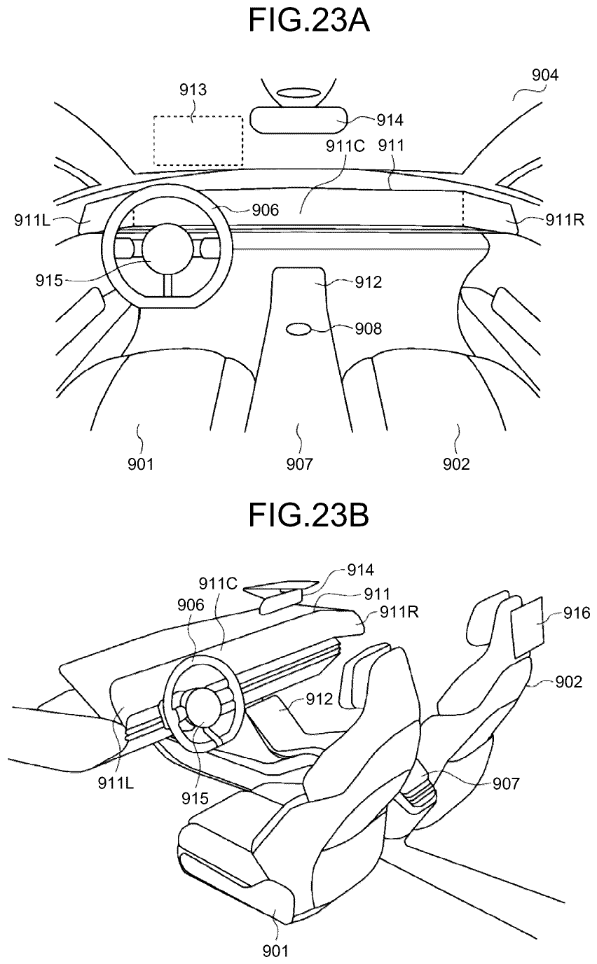

FIGS. 23A and 23B are diagrams illustrating an internal configuration of an automobile having the display device 100 according to the embodiment of the present disclosure as a display device. Specifically, FIG. 23A is a diagram illustrating a state of the inside of the automobile from the rear to the front of the automobile, and FIG. 23B is a diagram illustrating a state of the inside of the automobile from the oblique rear to the oblique front of the automobile.

The automobile illustrated in FIGS. 23A and 23B has a center display 911, a console display 912, a head-up display 913, a digital rear mirror 914, a steering wheel display 915, and a rear entertainment display 916. The display device 100 according to the embodiment of the present disclosure can be applied to some or all of the above displays. By applying the display device 100 according to the embodiment of the present disclosure, the image display surfaces of the center display 911, the console display 912, the head-up display 913, the digital rear mirror 914, the steering wheel display 915, and the rear entertainment display 916 can be made wider.

The center display 911 is disposed on a center console 907 at a position facing a driver's seat 901 and a passenger seat 902. FIGS. 23A and 23B illustrate an example of the center display 911 having a horizontally long shape extending from the driver's seat 901 side to the passenger seat 902 side, but the screen size and the arrangement place of the center display 911 are arbitrary. The center display 911 can display information detected by various sensors (not illustrated). As a specific example, the center display 911 can display a captured image captured by an image sensor, a distance image indicating a distance to an obstacle in front of or on a side of the automobile measured by a time of flight (ToF) sensor, a body temperature of a passenger detected by an infrared sensor, and the like. The center display 911 can be used to display, for example, at least one of safety related information, operation related information, a life log, health related information, authentication and identification related information, or entertainment related information.

The safety related information is information such as doze detection, distraction detection, detection of a prank by a child riding together, presence or absence of attachment of a seat belt, and detection of a left occupant, and is information detected by, for example, a sensor (not illustrated) superimposed on a back side of the center display 911. The operation related information detects a gesture related to an operation of the occupant by using a sensor. The detected gesture may include operation of various equipment in the automobile. For example, operations of air conditioning equipment, a navigation device, an audio/visual (AV) device, a lighting device, and the like are detected. The life log includes a life log of all the occupants. For example, the life log includes an action record of each occupant in the automobile. By acquiring and saving the life log, it is possible to confirm the state of the occupant at the time of an accident. The health related information detects the temperature of the occupant by using a temperature sensor, and estimates the health state of the occupant on the basis of the detected temperature. Alternatively, the face of the occupant may be imaged by using an image sensor, and the health state of the occupant may be estimated from an imaged facial expression. Furthermore, a conversation may be made with the occupant in an automatic voice, and the health condition of the occupant may be estimated on the basis of a response content of the occupant. The authentication and identification related information includes a keyless entry function of performing face authentication by using a sensor, an automatic adjustment function of a seat height and a position by using face identification, and the like. The entertainment related information includes a function of detecting operation information of an AV device by the occupant by using a sensor, a function of recognizing the face of the occupant by the sensor and providing content suitable for the occupant by the AV device, and the like.

The console display 912 can be used to display life log information, for example. The console display 912 is disposed near a shift lever 908 of the center console 907 between the driver's seat 901 and the passenger seat 902. The console display 912 can also display information detected by various sensors (not illustrated). The console display 912 may display an image of a periphery of a vehicle captured by an image sensor, or may display a distance image indicating a distance to an obstacle in the periphery of the vehicle.

The head-up display 913 is virtually displayed behind a windshield 904 in front of the driver's seat 901. The head-up display 913 can be used to display, for example, at least one of the safety related information, the operation related information, the life log, the health related information, the authentication and identification related information, or the entertainment related information. Since the head-up display 913 is virtually disposed in front of the driver's seat 901 in many cases, the head-up display is suitable for displaying information directly related to an operation of the automobile such as a speed of the automobile and a remaining amount of fuel (battery). By applying the display device 100 according to the embodiment of the present disclosure to the head-up display 913, it is not necessary to provide the outer frame 454, and thus, the driver's view toward the front of the automobile can be prevented from being hindered.

The digital rear mirror 914 can display not only the rear of the automobile but also the state of the occupant in the back seat, and thus can be used to display the life log information, for example, by arranging a sensor (not illustrated) to overlap a back surface side of the digital rear mirror 914.

The steering wheel display 915 is disposed near the center of a steering wheel 906 of the automobile. The steering wheel display 915 can be used to display, for example, at least one of the safety related information, the operation related information, the life log, the health related information, the authentication and identification related information, or the entertainment related information. In particular, the steering wheel display 915, which is near a hand of the driver, is suitable for displaying the life log information such as the temperature of the driver, or for displaying information related to the operation of the AV device, the air conditioning equipment, and the like.

The rear entertainment display 916 is attached to a back side of the driver's seat 901 and the passenger seat 902, and is for viewing by the occupant in the back seat. The rear entertainment display 916 can be used to display, for example, at least one of the safety related information, the operation related information, the life log, the health related information, the authentication and identification related information, or the entertainment related information. In particular, the rear entertainment display 916, which is in front of the occupant in the back seat, displays information related to the occupant in the back seat. For example, information related to the operation of the AV device or the air conditioning equipment may be displayed, or a result of measuring the temperature or the like of the occupant in the back seat by a temperature sensor (not illustrated) may be displayed.

### 9. Supplement

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive various changes or modifications within the scope of the technical idea described in the claims, and it is naturally understood that the changes or modifications also belong to the technical scope of the present disclosure.

Furthermore, the effects described in the present specification are merely illustrative or exemplary, and are not restrictive. That is, the technology of the present disclosure can exhibit other effects obvious to those skilled in the art from the description of the present specification together with or instead of the above effects.

Note that the present technique can also have the following configurations.

(1) A display device comprising:
a stacked structure in which a first substrate having a display unit including a plurality of light emitting elements and a drive circuit unit provided around the display unit, and a second substrate that transmits light from the plurality of light emitting elements are stacked on each other; and
a light shielding structure including a first light shielding film that covers at least a part of the drive circuit unit and a second light shielding film that covers at least a part of a region facing the drive circuit unit on a surface of the second substrate facing the first substrate.
   (2) The display device according to (1), wherein the first light shielding film and the second light shielding film are provided such that at least a part of the first light shielding film and at least a part of the second light shielding film face each other.
   (3) The display device according to (2), wherein the first light shielding film and the second light shielding film are provided such that an entirety of the first light shielding film and an entirety of the second light shielding film overlap each other.
   (4) The display device according to (1), wherein the first light shielding film and the second light shielding film are provided so as not to overlap each other.
   (5) The display device according to any one of (1) to (4), wherein the first light shielding film and the second light shielding film have one or more openings.
   (6) The display device according to (5), wherein the first light shielding film and the second light shielding film have a lattice shape or a checkered pattern shape.
   (7). The display device according to (5) or (6), wherein an area of the opening provided in the second light shielding film in plan view is 25% or more of an area of the second light shielding film in plan view.
   (8) The display device according to any one of (1) to (7), wherein at least one of the first light shielding film or the second light shielding film includes an organic material film.
   (9) The display device according to (8), wherein at least one of the first light shielding film or the second light shielding film includes a color resist.
   (10) The display device according to (9), wherein at least one of the first light shielding film or the second light shielding film includes a plurality of the color resists that is stacked.
   (11) The display device according to (9) or (10), wherein the color resist includes at least one selected from the group consisting of a red resist, a green resist, a blue resist, and a black resist.
   (12) The display device according to any one of (1) to (7), wherein at least one of the first light shielding film or the second light shielding film includes an inorganic material film.
   (13) The display device according to (12), wherein at least one of the first light shielding film or the second light shielding film includes a low reflection metal film.
   (14) The display device according to (13), wherein at least one of the first light shielding film or the second light shielding film includes the low reflection metal film and a metal film that are stacked.
   (15) The display device according to (13) or (14), wherein the low reflection metal film is at least one selected from the group consisting of titanium nitride, titanium oxynitride, chromium, chromium oxide, and tungsten silicide.
   (16) The display device according to any one of (1) to (15), further comprising a sealing member including a photocurable resin that seals between the first substrate and the second substrate on an outer periphery of the stacked structure in plan view.
   (17) The display device according to (16), wherein the sealing member is provided to be in direct contact with a surface of the drive circuit unit.
   (18) The display device according to any one of (1) to (17), further comprising a resin including a photocurable resin that seals between the first substrate and the second substrate.
   (19) The display device according to any one of (1) to (18), wherein
the stacked structure has a rectangular shape in plan view, and
the light shielding structure is provided along at least a part of at least one of four sides of the stacked structure in plan view.
   (20) An electronic apparatus equipped with a display device,
the display device including
a stacked structure in which a first substrate having a display unit including a plurality of light emitting elements and a drive circuit unit provided around the display unit, and a second substrate that transmits light from the plurality of light emitting elements are stacked on each other, and
a light shielding structure including a first light shielding film that covers at least a part of the drive circuit unit and a second light shielding film that covers at least a part of a region facing the drive circuit unit on a surface of the second substrate facing the first substrate.

### REFERENCE SIGNS LIST

100, 100a DISPLAY DEVICE
102, 611, 802 DISPLAY UNIT
104 CIRCUIT UNIT
200 BP SUBSTRATE
202 LIGHT EMITTING UNIT
204 DRIVE CIRCUIT UNIT
300 COUNTER SUBSTRATE
302 CF UNIT
402, 404 LIGHT SHIELDING FILM
402f LOW REFLECTION METAL FILM
402m METAL FILM
404B, 404G, 404L, 404R COLOR RESIST
406 OPENING
450 SEALING MEMBER
452 RESIN
454 OUTER FRAME
500 DIGITAL STILL CAMERA
511 CAMERA BODY
512 IMAGING LENS UNIT
513 GRIP
514 MONITOR
515 ELECTRONIC VIEW FINDER
600 HEAD MOUNTED DISPLAY
612 EAR HOOK
630 EYEGLASS
631 LENS BARREL
632 BODY
633, 643 ARM
634 SEE-THROUGH HEAD MOUNTED DISPLAY
710 TELEVISION APPARATUS
711 VIDEO DISPLAY SCREEN UNIT
712 FRONT PANEL
713 FILTER GLASS
800 SMARTPHONE
901 DRIVER'S SEAT
902 PASSENGER SEAT
904 WINDSHIELD
906 STEERING WHEEL
907 CENTER CONSOLE
908 SHIFT LEVER
911 CENTER DISPLAY
912 CONSOLE DISPLAY
913 HEAD-UP DISPLAY
914 DIGITAL REAR MIRROR
915 STEERING WHEEL DISPLAY
916 REAR ENTERTAINMENT DISPLAY

1. A display device comprising:
a stacked structure in which a first substrate having a display unit including a plurality of light emitting elements and a drive circuit unit provided around the display unit, and a second substrate that transmits light from the plurality of light emitting elements are stacked on each other; and
a light shielding structure including a first light shielding film that covers at least a part of the drive circuit unit and a second light shielding film that covers at least a part of a region facing the drive circuit unit on a surface of the second substrate facing the first substrate.

2. The display device according to claim 1, wherein the first light shielding film and the second light shielding film are provided such that at least a part of the first light shielding film and at least a part of the second light shielding film face each other.

3. The display device according to claim 2, wherein the first light shielding film and the second light shielding film are provided such that an entirety of the first light shielding film and an entirety of the second light shielding film overlap each other.

4. The display device according to claim 1, wherein the first light shielding film and the second light shielding film are provided so as not to overlap each other.

5. The display device according to claim 1, wherein the first light shielding film and the second light shielding film have one or more openings.

6. The display device according to claim 5, wherein the first light shielding film and the second light shielding film have a lattice shape or a checkered pattern shape.

7. The display device according to claim 5, wherein an area of the opening provided in the second light shielding film in plan view is 25% or more of an area of the second light shielding film in plan view.

8. The display device according to claim 1, wherein at least one of the first light shielding film or the second light shielding film includes an organic material film.

9. The display device according to claim 8, wherein at least one of the first light shielding film or the second light shielding film includes a color resist.

10. The display device according to claim 9, wherein at least one of the first light shielding film or the second light shielding film includes a plurality of the color resists that is stacked.

11. The display device according to claim 9, wherein the color resist includes at least one selected from the group consisting of a red resist, a green resist, a blue resist, and a black resist.

12. The display device according to claim 1, wherein at least one of the first light shielding film or the second light shielding film includes an inorganic material film.

13. The display device according to claim 12, wherein at least one of the first light shielding film or the second light shielding film includes a low reflection metal film.

14. The display device according to claim 13, wherein at least one of the first light shielding film or the second light shielding film includes the low reflection metal film and a metal film that are stacked.

15. The display device according to claim 13, wherein the low reflection metal film is at least one selected from the group consisting of titanium nitride, titanium oxynitride, chromium, chromium oxide, and tungsten silicide.

16. The display device according to claim 1, further comprising a sealing member including a photocurable resin that seals between the first substrate and the second substrate on an outer periphery of the stacked structure in plan view.

17. The display device according to claim 16, wherein the sealing member is provided to be in direct contact with a surface of the drive circuit unit.

18. The display device according to claim 1, further comprising a resin including a photocurable resin that seals between the first substrate and the second substrate.

19. The display device according to claim 1, wherein
the stacked structure has a rectangular shape in plan view, and
the light shielding structure is provided along at least a part of at least one of four sides of the stacked structure in plan view.

20. An electronic apparatus equipped with a display device,
the display device including
a stacked structure in which a first substrate having a display unit including a plurality of light emitting elements and a drive circuit unit provided around the display unit, and a second substrate that transmits light from the plurality of light emitting elements are stacked on each other, and
a light shielding structure including a first light shielding film that covers at least a part of the drive circuit unit and a second light shielding film that covers at least a part of a region facing the drive circuit unit on a surface of the second substrate facing the first substrate.
